(19) United States
(12) Patent Application Publication
(10) Pub. No.: US 2009/0265538 A1
(43) Pub. Date: Oct. 22, 2009

(54) Method and Related Control Interface for Switching an Operating State in a Portable Electronic Device

(76) Inventor: Bing-Hang Wang, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/168,902

(22) Filed: Jul. 8, 2008

(30) Foreign Application Priority Data
Apr. 17, 2008 (TW) 097113960

(51) Int. Cl. G06F 9/00; H03K 17/00

(52) U.S. Cl. 713/100; 327/365

(57) ABSTRACT

A method for switching an operating state in a portable electronic device includes sending a switching signal when a plurality of specific pads of the portable electronic device are triggered simultaneously, and switching the operating state of the portable electronic device according to the switching signal.

### BACKGROUND OF THE INVENTION

1. Field of the Invention

The present invention relates to a method and related control interface for switching an operating state in a portable electronic device, and more particularly, to a method and related control interface for saving a power pad, thereby saving cost of manufacture and space.

2. Description of the Prior Art

A laptop (i.e., a notebook computer) has several advantages, such as a small-sized volume, lightweight, and convenient for carrying due to its portability, and provides powerful computation abilities and document or multimedia processing functions anywhere and anytime, allowing a user to work in any location outside an office.

The notebook computer can enhance utility convenience. However, as the need of portability increases, the industry is expected to develop slighter and lower-cost notebook computers.

### SUMMARY OF THE INVENTION

It is therefore a primary objective of the claimed invention to provide a method and related control interface for switching an operating state in a portable electronic device.

The present invention discloses a method for switching an operating state in a portable electronic device, which comprises sending a switching signal when a plurality of specific pads of the portable electronic device are triggered simultaneously, and switching the operating state of the portable electronic device according to the switching signal.

The present invention further discloses a control interface for switching an operating state in a portable electronic device, which comprises a plurality of pads, an identification unit and a control unit. The identification unit is coupled to the plurality of pads, for sending a switching signal when a plurality of specific pads of the plurality of pads are triggered simultaneously. The control unit is coupled to the identification unit, for switching an operating state of the portable electronic device according to the switching signal.

The present invention further discloses a portable computer system capable of switching an operating state with combined pads, which comprises a host, a display device and an input interface. The host is utilized for executing functions of the portable computer system. The display device is coupled to the host, for displaying image signals outputted by the host. The input interface is coupled to the host for receiving control signals for controlling the host, and comprises a keyboard, an identification unit and a control unit. The keyboard comprises a plurality of pads. The identification unit is coupled to the keyboard, for sending a switching signal when a plurality of specific pads of the keyboard are triggered simultaneously. The control unit is coupled to the identification unit and the host, for switching the operating state of the host according to the switching signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a procedure according to an embodiment of the present invention.

FIG. 2 is a functional block diagram of a control interface in a portable electronic device according to an embodiment of the present invention.

FIG. 3 is a functional block diagram of a portable computer system according to an embodiment of the present invention.

### DETAILED DESCRIPTION

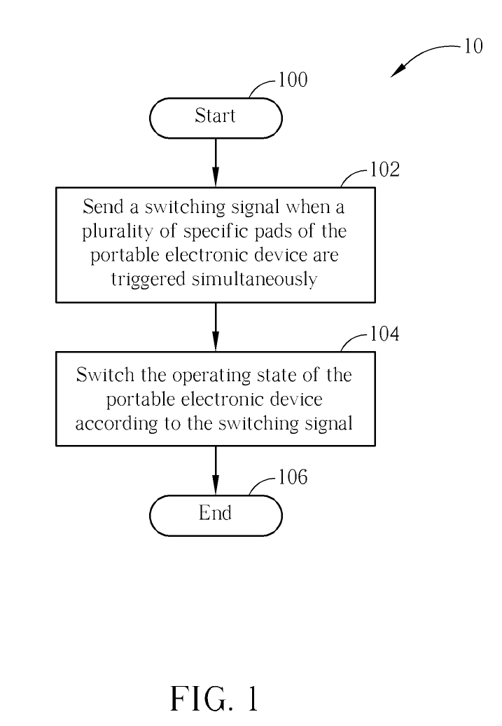

Please refer to FIG. 1. FIG. 1 is a schematic diagram of a procedure 10 according to an embodiment of the present invention. The procedure 10 is utilized for switching an operating state in a portable electronic device. Preferably, the portable electronic device is a portable computer system. The procedure 10 comprises the following steps:

Step100: Start.

Step102: Send a switching signal when a plurality of specific pads of the portable electronic device are triggered simultaneously.

Step104: Switch the operating state of the portable electronic device according to the switching signal.

Step106: End.

According to the procedure 10, when a plurality of specific pads of the portable electronic device are triggered simultaneously, the present invention sends a switching signal, and switches the operating state of the portable electronic device according to the switching signal. In other words, the present invention switches the operating state of the portable electronic device when the plurality of specific pads are triggered simultaneously.

For example, if the portable electronic device is in an ON state, when the plurality of specific pads are pressed simultaneously, the present invention can switch the operating state of the portable electronic device from the ON state to an OFF state. On the contrast, if the portable electronic device is in the OFF state, when the plurality of specific pads are pressed simultaneously, the present invention can switch the operating state of the portable electronic device from the OFF state to the ON state. In other words, the present invention can perform start and shutdown operations without using a power pad. As a result, the power pad can be reduced to save cost, and more importantly, to save required space.

The present invention switches the operating state of the portable electronic device when the plurality of specific pads of the portable electronic device are triggered simultaneously. Note that, the number of the plurality of specific pads is not limited. For example, if the number of the plurality of specific pads is two, then when the two specific pads of the portable electronic device are triggered simultaneously, the present invention can switch the operating state of the portable electronic device. Moreover, the portable electronic device may comprise pads for other purpose. In addition, materials, types and manufacturing of the plurality of specific pads are not limited. For example, the plurality of specific pads can be displayed by means of images on a touch panel of the portable electronic device.

Therefore, via the procedure 10, when the plurality of specific pads of the portable electronic device are triggered simultaneously, the present invention sends the switching signal, and switches the operating state of the portable electronic device according to the switching signal, so as to save cost and space of the pads.

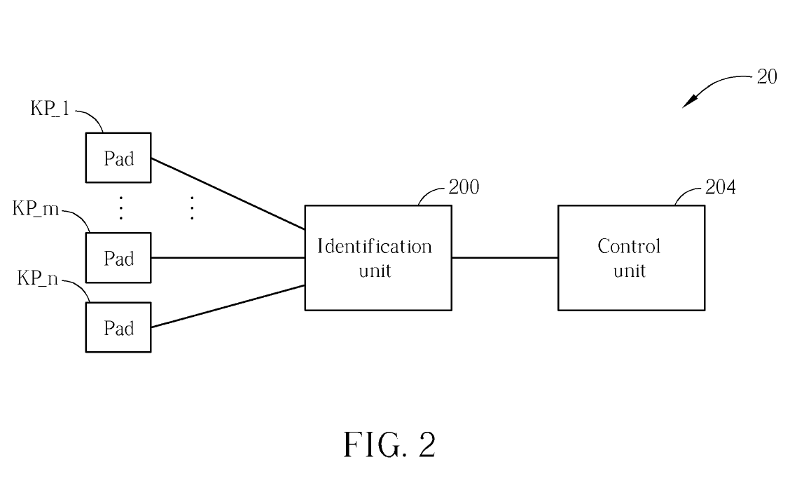

Please refer to FIG. 2. FIG. 2 is a functional block diagram of a control interface 20 in a portable electronic device according to an embodiment of the present invention. Preferably, the portable electronic device is a portable computer system. The control interface 20 comprises pads KP_1˜KP_n, an identification unit 200 and a control unit 204. The identification unit 200 is coupled to the pads KP_1˜KP_n and the control unit 204. When a plurality of specific pads of the pads KP_1˜KP_n are triggered simultaneously, the identification unit 200 sends a switching signal to the control unit 204 to switch an operating state of the portable electronic device. For example, if the portable electronic device is in an ON state, when pads KP_1 and KP_m of the pads KP_1˜KP_n are pressed simultaneously, the control interface 20 can switch the operating state of the portable electronic device from the ON state to an OFF state. On the contrast, if the portable electronic device is in the OFF state, when the pads KP_1 and KP_m are pressed simultaneously, the control interface 20 can switch the operating state of the portable electronic device from the OFF state to the ON state. In other words, the control interface 20 can perform start and shutdown operations without using a power pad. As a result, the power pad can be omitted to save cost of material and space-utility.

Note that, the number of the plurality of specific pads for triggering output of the switching signal in the pads KP_1˜KP_n is not limited. In addition, materials, types and manufacturing of the pads KP_1˜KP_n are not limited. For example, the pads KP_1˜KP_n can be displayed by means of images on a touch panel of the portable electronic device.

Therefore, via the control interface 20, when the plurality of specific pads of the pads KP_1˜KP_n are triggered simultaneously, the identification unit 200 sends the switching signal to the control unit 204 to switch the operating state of the portable electronic device accordingly, so as to save cost and space of the pads.

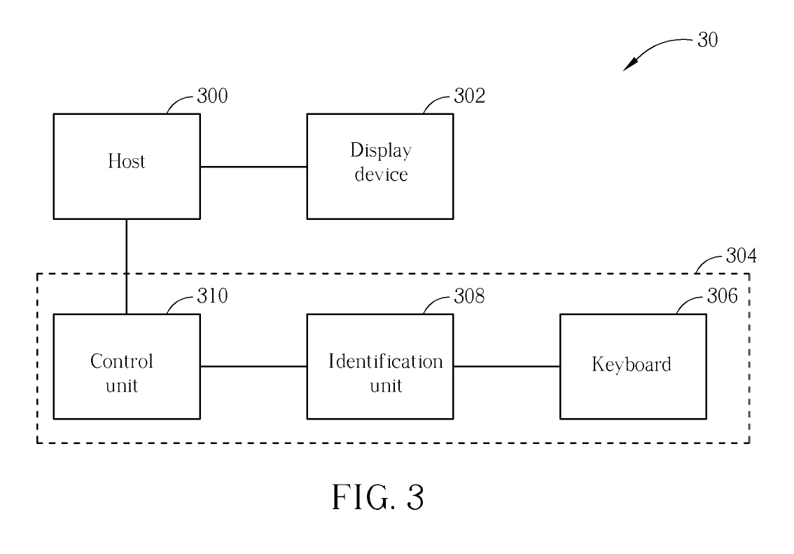

The control interface 20 shown in FIG. 2 is merely an exemplary embodiment of the present invention, and those skilled in the art can make alternations and modifications according to practical demands. For example, please refer to FIG. 3. FIG. 3 is a functional block diagram of a portable computer system 30 according to an embodiment of the present invention. The portable computer system 30 can reduce manufacturing cost, and comprises a host 300, a display device 302 and an input interface 304. The host 300 is utilized for executing functions of the portable computer system 30. The input interface 304 is coupled to the host 300, for receiving control signals outputted by a user to control the host 300, and has a structure similar to the control interface 20 shown in FIG. 2. The input interface 304 comprises a keyboard 306, an identification unit 308 and a control unit 310. The keyboard 306 comprises a plurality of pads for receiving inputting signals from the user. The identification unit 308 is coupled to the keyboard 306, and utilized for sending a switching signal to the control unit 310 when a plurality of specific pads of the keyboard 306 are triggered simultaneously. The control unit 310 switches the operating state of the host 300 according to the switching signal, i.e. switching from an ON state to an OFF state or switching from an OFF state to an ON state.

Therefore, in the portable computer system 30, when the plurality of specific pads of the keyboard 306 are triggered simultaneously, the control unit 310 can switch the operating state of the host 300. In other words, the user can perform start and shutdown operations of the portable computer system 30 without using a power pad. As a result, the power pad can be reduced to save cost of materials and space. Certainly, the number of the plurality of specific pads for outputting the switching signal in the keyboard 306 is not limited. In addition, material, type and manufacturing of the keyboard 306 are not limited. For example, if the display device 302 comprises a touch panel, the keyboard 306 can be displayed by means of images on the touch panel.

In conclusion, when a plurality of specific pads are triggered simultaneously, the present invention can switch an operating state of a portable electronic device, so as to save a power pad, thereby saving cost of manufacturing and space.

Those skilled in the art will readily observe that numerous modifications and alterations of the device and method may be made while retaining the teachings of the invention.

What is claimed is:

1. A method for switching an operating state in a portable electronic device comprising:
sending a switching signal when a plurality of specific pads of the portable electronic device are triggered simultaneously; and
switching the operating state of the portable electronic device according to the switching signal.

2. The method of claim 1, wherein switching the operating state of the portable electronic device according to the switching signal comprises switching the operating state of the portable electronic device from an ON state to an OFF state according to the switching signal.

3. The method of claim 1, wherein switching the operating state of the portable electronic device according to the switching signal comprises switching the operating state of the portable electronic device from an OFF state to an ON state according to the switching signal.

4. The method of claim 1, wherein the plurality of specific pads are displayed by means of images on a touch panel of the portable electronic device.

5. The method of claim 1, wherein the portable electronic device is a portable computer system.

6. A control interface in a portable electronic device comprising:
a plurality of pads;
an identification unit coupled to the plurality of pads, for sending a switching signal when a plurality of specific pads of the plurality of pads are triggered simultaneously; and
a control unit coupled to the identification unit, for switching an operating state of the portable electronic device according to the switching signal.

7. The control interface of claim 6, wherein the control unit switches the operating state of the portable electronic device from an ON state to an OFF state according to the switching signal.

8. The control interface of claim 6, wherein the control unit switches the operating state of the portable electronic device from an OFF state to an ON state according to the switching signal.

9. The control interface of claim 6, wherein the plurality of pads are displayed by means of images on a touch panel of the portable electronic device.

10. The control interface of claim 6, wherein the portable electronic device is a portable computer system.

11. A portable computer system capable of switching an operating state with combined pads comprising:
a host for executing functions of the portable computer system;
a display device coupled to the host, for displaying image signals outputted by the host; and
an input interface coupled to the host, for receiving control signals for controlling the host, the input interface comprising:
a keyboard comprising a plurality of pads;
an identification unit coupled to the keyboard, for sending a switching signal when a plurality of specific pads of the keyboard are triggered simultaneously; and
a control unit coupled to the identification unit and the host, for switching the operating state of the host according to the switching signal.

12. The portable computer system of claim 11, wherein the control unit switches the operating state of the host from an ON state to an OFF state according to the switching signal.

13. The portable computer system of claim 11, wherein the control unit switches the operating state of the host from an OFF state to an ON state according to the switching signal.

14. The portable computer system of claim 11, wherein the display device comprises a touch panel.

15. The portable computer system of claim 14, wherein the keyboard is displayed by means of images on the touch panel.
